(19) United States
(12) Patent Application Publication
(10) Pub. No.: US 2026/0246441 A1
(43) Pub. Date: Aug. 20, 2026

(54) FILTER AND MULTIPLEXER

(71) Applicant: ANHUI YUNTA ELECTRONIC TECHNOLOGIES CO., LTD., Hefei (CN)

(72) Inventors: Chenggong HE, Hefei (CN); Qilin SHI, Hefei (CN); Jian NIU, Hefei (CN); Chengjie ZUO, Hefei (CN); Jun HE, Hefei (CN)

(21) Appl. No.: 18/859,474

(22) PCT Filed: Jul. 24, 2024
(86) PCT No.: PCT/CN2024/107190

§ 371 Date: Oct. 23, 2024

(30) Foreign Application Priority Data
Nov. 9, 2023 (CN) 202311501786.0

(51) Int. Cl. H03H 7/075; H03H 7/01; H03H 7/46

(52) U.S. Cl. CPC H03H 7/075; H03H 7/065; H03H 7/07; H03H 7/1791; H03H 9/542

(57) ABSTRACT

A filter includes a first port, a second port and at least one filtering unit. Each filtering unit includes a T network and a resonator. The T network includes a first capacitive element, a second capacitive element and a first element. The first capacitive element and the second capacitive element are connected in series between the first port and the second port, the first element is connected to a node between the first capacitive element and the second capacitive element, and the resonator is connected in parallel with T the network.

### CROSS-REFERENCE TO RELATED APPLICATIONS

This is a National Stage Application, filed under 35 U.S.C.371 based on International Patent Application No. PCT/CN2024/107190 filed on Jul. 24, 2024, which claims priority to Chinese Patent Application No. 202311501786.0 filed on Nov. 9, 2023, the disclosures of which are incorporated herein by reference in their entireties.

### TECHNICAL FIELD

Embodiments of the present application relate to the technical filed of signal processing, for example, a filter and a multiplexer.

### BACKGROUND

In the communication system, signal interference can significantly reduce signal transmission efficiency, while filters can effectively reject out-of-band signal interference to improve the signal transmission efficiency. Therefore, in modern communication, there is an increasing demand for filters with low insertion loss and high roll-off.

### SUMMARY

The present application provides a filter and a multiplexer.

In a first aspect, embodiments of the present application provide a filter. The filter includes a first port, a second port and at least one filtering unit.

Each filtering unit includes a T network and a resonator, where the T network includes a first capacitive element, a second capacitive element and a first element; the first capacitive element and the second capacitive element are connected in series between the first port and the second port, the first element is connected to a node between the first capacitive element and the second capacitive element, and the resonator is connected in parallel with the T network.

In some embodiments, the first element comprises a first inductive element, a first terminal of the first inductive element is connected to the node, and a second terminal of the first inductive element serves as a third port of the filter.

In some embodiments, the first element includes a third capacitive element, a first terminal of the third capacitive element is connected to the node, and a second terminal of the third capacitive element serves as a third port of the filter.

In some embodiments, the first element includes a first inductive element and a third capacitive element, and the first inductive element and the third capacitive element are connected to the node after being connected in series or parallel.

In some embodiments, the filter further includes an LC filtering element, where the LC filtering element and the at least one filtering unit are connected in series between the first port and the second port.

In some embodiments, the filter further includes at least two filtering units, and the at least two filtering units are connected in series between the first port and the second port.

In some embodiments, the filter further includes a fourth port, where the fourth port is provided between the at least two filtering units.

In some embodiments, when the filter includes the LC filtering unit, the LC filtering unit is connected in series between the at least two filtering units.

In some embodiments, transmission zeros of different filtering units of the at least two filtering units correspond to equal frequencies.

In a second aspect, the embodiments of the present application further provide a multiplexer, and the multiplexer includes a first terminal, multiple second terminals and the filter according to the first aspect.

According to the technical solutions of the embodiments of the present application, the resonator and the T network in the filtering unit are connected in parallel so that a Y parameter of the resonator and a Y parameter of the T network are added together, so two transmission zeros are formed in an adjacent band range on a low-frequency side of a passband of the filter.

### BRIEF DESCRIPTION OF DRAWINGS

FIG. 1 is a structural diagram of a filter according to embodiments of the present application;

FIG. 2 is a structural diagram of an LC filter in the related art;

FIG. 3 is a graph showing the performance comparison of different filters according to embodiments of the present application;

FIG. 4 is a structural diagram of another filter according to embodiments of the present application;

FIG. 5 is a structural diagram of another filter according to embodiments of the present application;

FIG. 6 is a structural diagram of another filter according to embodiments of the present application;

FIG. 7 is a structural diagram of another filter according to embodiments of the present application;

FIG. 8 is a structural diagram of another filter according to embodiments of the present application;

FIG. 9 is a structural diagram of another filter according to embodiments of the present application; and FIG. 10 is a structural diagram of a multiplexer according to embodiments of the present application.

### DETAILED DESCRIPTION

FIG. 1 is a structural diagram of a filter according to embodiments of the present application. As shown in FIG. 1, the filter includes a first port A, a second port B and at least one filtering unit 10. Each filtering unit 10 includes a T network 11 and a resonator 12. The T network 11 includes a first capacitive element C1, a second capacitive element C2 and a first element M1. The first capacitive element C1 and the second capacitive element C2 are connected in series between the first port A and the second port B. The first element M1 is connected to a node D between the first capacitive element C1 and the second capacitive element C2, and the resonator 12 is connected in parallel with the T network 11.

For example, the first capacitive element C1 and the second capacitive element C2 are connected in series between the first port A and the second port B, and the first port A and the second port B may serve as two ports of the T network respectively. Moreover, a first terminal of the first element M1 is connected to the node D between the first capacitive component C1 and the second capacitive component C2, and a second terminal of the first element M1 may be another port of the T network. Exemplarily, FIG. 1 exemplarily shows that the first element M1 may include an inductive element, and the inductive element may include an actually disposed inductor or a parasitic inductor. When the first capacitive element C1 and the second capacitive element C2 are connected in series between the first port A and the second port B, a Y parameter of the T network does not have a minimum value. The Y parameter is admittance of the T network and is reciprocal to impedance. When the Y parameter of the T network does not have a minimum value, the T network does not have a maximum value of the impedance, that is, no rejection point (that is, no transmission zero) exists in a transmission characteristic curve of the T network. The first port A and the second port B of the filter may be an input terminal and an output terminal of the filter respectively and may be connected to external circuit elements respectively. When the first terminal of the first component M1 is connected to the node D, the second terminal of the first element M1 may serve as a third port E of the filter, and the third port E may be connected to an external circuit element, which is not limited here.

The resonator 12 may be an acoustic wave resonator. Exemplarily, the resonator 12 may be at least one of a bulk acoustic wave (BAW) resonator, a surface acoustic wave (SAW) resonator or a film bulk acoustic resonator (FBAR) filter. The resonator 12 has bandpass characteristics and has a transmission zero on a high-frequency side of a passband. That is, in transmission characteristics of the resonator 12, a Y parameter has a minimum value on the high-frequency side of the passband, so the resonator 12 has a strong rejection effect on the frequency corresponding to the transmission zero, and thus the resonator 12 has a large roll-off slope on the frequency corresponding to the transmission zero. In the filtering unit 10, when the T network 11 composed of the first capacitive element C1, the second capacitive element C2 and the first element M1 is connected in parallel with the resonator 12, a Y parameter of the filtering unit 10 is the sum of the Y parameter of the T network 11 and the Y parameter of the resonator 12. On a low-frequency side of the passband of the resonator 12, the value of the Y parameter of the T network 11 composed of the first capacitive element C1, the second capacitive element C2 and the first element M1 and the value of the Y parameter of the resonator 12 are of contrary signs, so the sum of the Y parameter of the T network 11 and the Y parameter of the resonator 12 can generate an additional minimum value in an adjacent band range on the low-frequency side of the passband. That is, in the filtering unit 10, an additional transmission zero is generated in the adjacent band on the low-frequency side of the passband, which can increase the roll-off slope of the adjacent band on the low-frequency side of the passband, improve the adjacent-band rejection on the low-frequency side of the passband of the filter, and thus improve the filtering performance of the filter. Moreover, on the high-frequency side of the passband of the resonator 12, the frequency of the transmission zero corresponding to the sum of the Y parameter of the T network 11 and the Y parameter of the resonator 12 shifts towards the low-frequency side relative to the frequency of the transmission zero of the resonator 12, so the inherent transmission zero of the resonator 12 shifts to the adjacent band range on the low-frequency side of the passband, and thus a second transmission zero can be formed in the adjacent band on the low-frequency side of the passband of the filter. In this manner, the roll-off slope of the adjacent band on the low-frequency side of the passband can be increased, the adjacent band rejection on the low-frequency side of the passband of the filter can be improved, and thus the filtering performance of the filter can be enhanced. The adjacent band may be a frequency band higher or lower than the passband, and a transition band between the adjacent band and the passband merely ranges from zero MHz to tens of MHz, and the bandwidth of the adjacent band is within a frequency range of 10% higher than the center frequency of the passband.

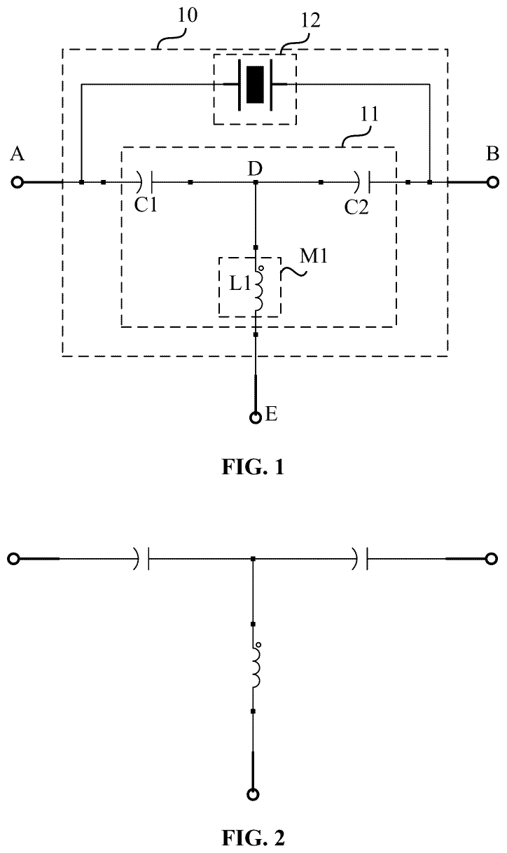

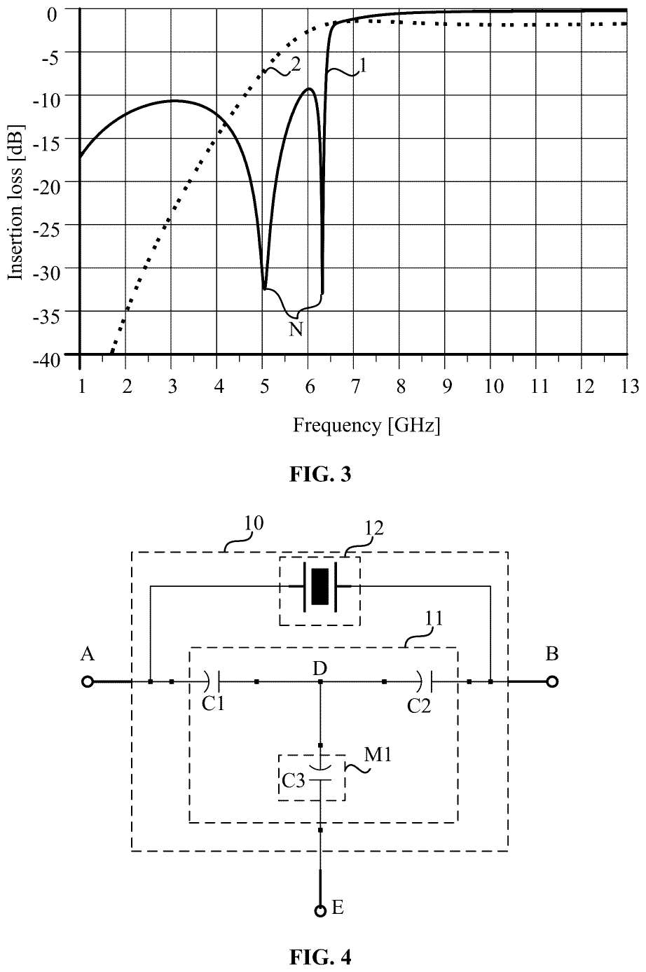

Exemplarily, FIG. 2 is a structural diagram of an LC filter in the related art. The specific structure of the LC filter is the same as the T network in FIG. 1. FIG. 3 is a graph showing the performance comparison of different filters according to embodiments of the present application. An abscissa of the graph represents a frequency, and an ordinate of the graph represents insertion loss. Curve 1 is a frequency-insertion loss curve of the filter provided in FIG. 1, and curve 2 is a frequency-insertion loss curve of the filter provided in FIG. 2. As shown in FIG. 3, curve 1 forms two transmission zeros N in the adjacent band range on the low-frequency side of the passband, and a rejection level can reach below −30 dB. Curve 2 has no transmission zero in the adjacent band range on the low-frequency side of the passband and has a relatively low rejection level. It can be seen that when a resonator 12 is connected in parallel with the T network on the basis of the LC filter provided in FIG. 2, two transmission zeros can be formed in the adjacent band range on the low-frequency side of the passband of the filter, which can significantly improve the roll-off slope of the adjacent band on the low-frequency side of the passband, greatly enhance the adjacent-band rejection on the low-frequency side of the passband of the filter, and thus improve the filtering performance of the filter.

According to the technical solutions of the embodiments, the resonator and the T network in the filtering unit are connected in parallel so that the Y parameter of the resonator and the Y parameter of the T network are added together, so two transmission zeros are formed in the adjacent band range on the low-frequency side of the passband of the filter, which significantly improves the roll-off slope of the adjacent band on the low-frequency side of the passband of the filter, greatly improves the adjacent-band rejection on the low-frequency side of the passband of the filter, and thus enhances the filtering performance of the filter.

On the basis of the preceding technical solutions, with continued reference to FIG. 1, the first element M1 includes a first inductive element L1, a first terminal of the first inductive element L1 is connected to the node D, and a second terminal of the first inductive element L1 serves as the third port E of the filter.

For example, the first element M1 may include a first inductive element L1, the first inductive element L1 forms a T-type LC filtering network with the first capacitive element C1 and the second capacitive element C2 for filtering out-of-band interference signals and thus improving the signal transmission efficiency. The third port E may be connected to an external circuit element, so the filter can be connected to different types of external circuits, which increases the application range of the filter.

FIG. 4 is a structural diagram of another filter according to embodiments of the present application. As shown in FIG. 4, the first element M1 includes a third capacitive element C3, a first terminal of the third capacitive element C3 is connected to the node D, and a second terminal of the third capacitive element C3 serves as the third port E of the filter.

For example, the first element M1 may include a third inductive element C3, the third inductive element C3 forms a T-type capacitive filtering network with the first capacitive element C1 and the second capacitive element C2 for filtering out-of-band interference signals and thus improving the signal transmission efficiency. The third port E may be connected to an external circuit element, so the filter can be connected to different types of external circuits, which increases the application range of the filter.

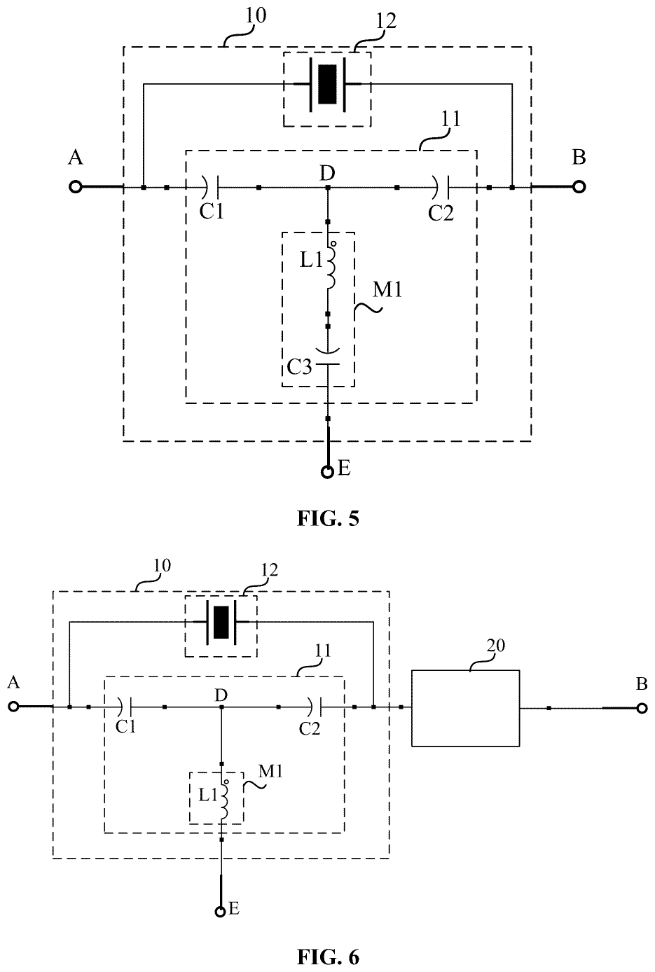

FIG. 5 is a structural diagram of another filter according to embodiments of the present application. As shown in FIG. 5, the first element M1 includes a first inductive element L1 and a third capacitive element C3, and the first inductive element L1 and the third capacitive element C3 are connected to the node D after being connected in series or parallel.

For example, FIG. 5 exemplarily shows that a first terminal of a series circuit formed by the first inductive element L1 and the third capacitive element C3 connected in series is connected to the node D, and a second terminal of the series circuit formed by the first inductive element L1 and the third capacitive element C3 connected in series serves as the third port E of the filter. After the first inductive element L1 and the third capacitive element C3 are connected in series, the first inductive element L1 and the third capacitive element C3 form a T-type LC filtering network with the first capacitive element C1 and the second capacitive element C2 for filtering out-of-band interference signals and thus improving the signal transmission efficiency. The third port E may be connected to an external circuit element, so the filter can be connected to different types of external circuits, which increases the application range of the filter.

It is to be noted that in other embodiments, the first element M1 may further include multiple inductive elements and/or multiple capacitive elements, and the multiple inductive elements and/or the multiple capacitive elements may be connected in series and/or parallel. Alternatively, the first element M1 may further include a resistive element, and the resistive element is connected in series or parallel to the inductive element and/or the capacitive element for adjusting a resonant frequency of the T network, which is not limited here.

FIG. 6 is a structural diagram of another filter according to embodiments of the present application. As shown in FIG. 6, the filter further includes an LC filtering unit 20, and the LC filtering unit 20 and the filtering unit 10 are connected in series between the first port A and the second port B.

For example, the LC filtering unit 20 can adjust the passband of the filter so that the filter has a relatively wide passband. When the filter includes both the LC filtering unit 20 and the filtering unit 10, it can be ensured that the filter has a relatively wide passband, the roll-off slope of the adjacent band on the low-frequency side of the passband of the filter can also be increased, so the adjacent-band rejection on the low-frequency side of the passband of the filter can be greatly improved, and thus the filtering performance of the filter can be improved.

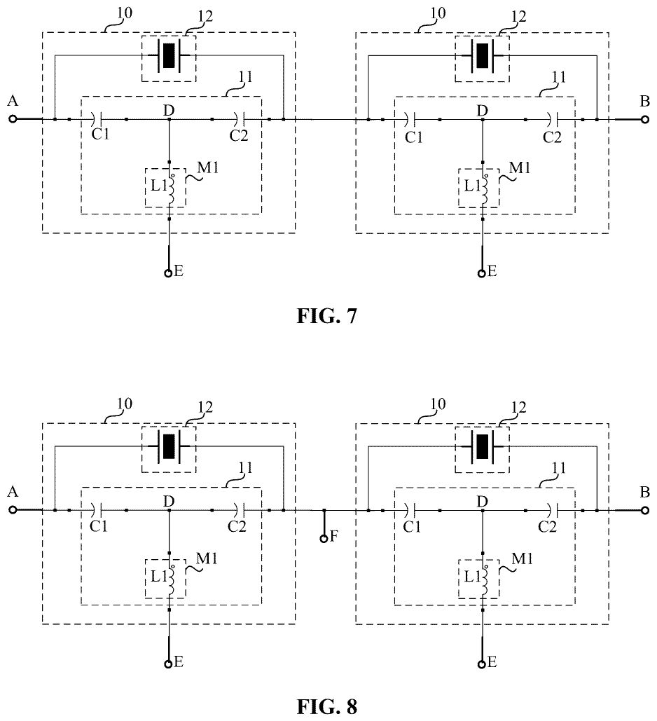

FIG. 7 is a structural diagram of another filter according to embodiments of the present application. As shown in FIG. 7, the filter includes at least two filtering units 10, and the at least two filtering units 10 are connected in series between the first port A and the second port B.

For example, when the at least two filtering units 10 are connected in series between the first port A and the second port B, different filtering units 10 can each generate two transmission zeros in the adjacent band on the low-frequency side of the passband of the filter, so the at least two filtering units 10 can each significantly increase the roll-off slope of the adjacent band on the low-frequency side of the passband, improve the adjacent-band rejection on the low-frequency side of the passband of the filter, and thus enhance the filtering performance of the filter. Exemplarily, FIG. 7 exemplarily shows that the filter includes two filtering units 10. Referring to FIG. 3, when the filter includes one filtering unit 10, the rejection level of the filter in the adjacent band range on the low-frequency side of the passband is around −32 dB. When the filter includes two filtering units 10, and frequencies of transmission zeros generated by the two filtering units 10 are equal to frequencies of two transmission zeros in FIG. 3, the corresponding rejection level of the filter at the transmission zeros on the low-frequency side of the passband can reach about −40 dB. In this manner, the roll-off slope of the adjacent band on the low-frequency side of the passband is improved, the adjacent-band rejection on the low-frequency side of the passband of the filter is improved, and thus the filtering performance of the filter is improved.

It is to be noted that in other embodiments, the filter may include multiple filtering units 10, and the multiple filtering units 10 may be connected in series between the first port A and the second port B, which is not limited here.

On the basis of the preceding technical solutions, transmission zeros of different filtering units 10 correspond to equal frequencies.

For example, parameters of the T network 11 in different filtering units 10 may be the same, and parameters of the resonator 12 in different filtering units 10 may be the same, so transmission zeros of different filtering units 10 correspond to equal frequencies. In this manner, the different filtering units 10 have the same passband frequency and form transmission zeros at the same frequency, so the roll-off slope of the adjacent band on the low-frequency side of the passband can be increased. Exemplarily, in different filtering units 10, T networks 11 have the same elements, and elements at the same position have the same parameters. Moreover, resonators 12 in different filtering units 10 have the same parameters, so different filtering units 10 can have equal resonant frequencies.

It is to be noted that in other embodiments, transmission zeros of different filtering units 10 may correspond to different frequencies, so the filter has multiple transmission zeros in the adjacent band range on the low-frequency side of the passband. Compared with the case where one filtering unit 10 has two transmission zeros, the roll-off slope of the adjacent band on the low-frequency side of the passband can also be increased. Exemplarily, in different filtering units 10, T networks 11 may have different elements, and/or elements at the same position have different parameters, and/or resonators 12 in different filtering units 10 have different parameters.

FIG. 8 is a structural diagram of another filter according to embodiments of the present application. As shown in FIG. 8, the filter further includes a fourth port F, and the fourth port F is provided between filtering units 10.

For example, FIG. 8 exemplarily shows that the filter includes two filtering units 10, and a fourth port F is provided between the two filtering units 10. The fourth port F may be connected to an external circuit element, so the filter can be connected to different types of external circuits, which increases the application range of the filter. In addition, the fourth port F may be connected to an equivalent element with large impedance, so the fourth port F may equivalently disconnect the circuit to satisfy different use scenarios of the filter.

It is to be noted that when the filter includes multiple filtering units 10, the fourth port F may be provided between two adjacent filtering units 10, and in this case, the filter may include multiple fourth ports F. Alternatively, the fourth port F may be provided between non-adjacent filtering units 10, and in this case, the filter may include at least one fourth port F, which is not limited here.

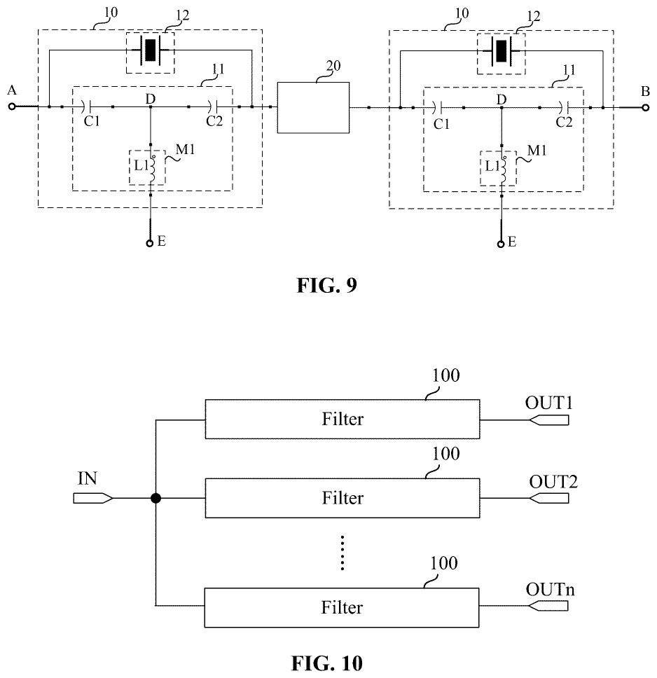

FIG. 9 is a structural diagram of another filter according to embodiments of the present application. As shown in FIG. 9, when the filter includes the LC filtering unit 20, the LC filtering unit 20 is connected in series between at least two filtering units 10.

For example, FIG. 9 exemplarily shows that the filter includes two filtering units 10 and one LC filtering unit 20, and the LC filtering unit 20 is connected in series between the two filtering units 10. In this manner, different filtering units 10 can be separated.

It is to be noted that in other embodiments, the LC filtering unit 20 may be disposed between the first port A and the filtering unit 10 or between the second port B and the filtering unit 10. When the filter includes multiple LC filtering units 20, different LC filtering units 20 may be connected in series at any position between the first port A and the second port B, which is not limited here.

Embodiments of the present application further provide a multiplexer. FIG. 10 is a structural diagram of a multiplexer according to embodiments of the present application. As shown in FIG. 10, the multiplexer includes filters 100, and each of the filters 100 is provided in any embodiment of the present application.

With continued reference to FIG. 10, the multiplexer includes one first terminal IN and at least two second terminals. Each filter 100 is connected in series between the first terminal IN and any second terminal of the multiplexer.

For example, FIG. 10 exemplarily shows that the multiplexer includes one first terminal IN and n second terminals which are OUT1, OUT2, . . . and OUTn respectively. Each filter 100 is connected in series between the first terminal IN and one second terminal. For example, the first filter 100 is connected in series between the first terminal IN and the second terminal OUT1, the second filter 100 is connected in series between the first terminal IN and the second terminal OUT2, and so on. The multiplexer has the filter 100 provided in any embodiment of the present application, thus having the same beneficial effects as the filter 100, that is, the roll-off slope of the adjacent band on the low-frequency side of the passband of the multiplexer is increased, the adjacent-band rejection on the low-frequency side of the passband of the filter is greatly improved, and thus the filtering performance of the filter is enhanced.

It is to be noted that the multiplexer may further include another filter connected in series between the first terminal IN and any second terminal. The another filter may be a low-pass filter, a high-pass filter or a bandpass filter, which is not limited in the embodiments of the present application.

What is claimed is:

1. A filter, comprising a first port, a second port and at least one filtering unit, wherein
each filtering unit of the at least one filtering unit comprises a T network and a resonator;
the T network comprises a first capacitive element, a second capacitive element and a first element; and
the first capacitive element and the second capacitive element are connected in series between the first port and the second port, the first element is connected to a node between the first capacitive element and the second capacitive element, and the resonator is connected in parallel with the T network.

2. The filter according to claim 1, wherein the first element comprises a first inductive element, a first terminal of the first inductive element is connected to the node, and a second terminal of the first inductive element serves as a third port of the filter.

3. The filter according to claim 1, wherein the first element comprises a third capacitive element, a first terminal of the third capacitive element is connected to the node, and a second terminal of the third capacitive element serves as a third port of the filter.

4. The filter according to claim 1, wherein the first element comprises a first inductive element and a third capacitive element, and a circuit formed by the first inductive element and the third capacitive element connected in series or parallel is connected to the node.

5. The filter according to claim 1, further comprising an LC filtering element, wherein the LC filtering element and the at least one filtering unit are connected in series between the first port and the second port.

6. The filter according to claim 1, wherein the filter comprises at least two filtering units, and the at least two filtering units are connected in series between the first port and the second port.

7. The filter according to claim 6, further comprising a fourth port, wherein the fourth port is provided between the at least two filtering units.

8. The filter according to claim 6, wherein the filter further comprises the LC filtering unit, and the LC filtering unit is connected in series between the at least two filtering units.

9. The filter according to claim 6, wherein transmission zeros of different filtering units of the at least two filtering units correspond to equal frequencies.

10. A multiplexer, comprising a first terminal, a plurality of second terminals and a plurality of filters;
wherein a filter of plurality of filters comprises a first port, a second port and at least one filtering unit;
wherein each filtering unit of the at least one filtering unit comprises a T network and a resonator;
the T network comprises a first capacitive element, a second capacitive element and a first element; and
the first capacitive element and the second capacitive element are connected in series between the first port and the second port, the first element is connected to a node between the first capacitive element and the second capacitive element, and the resonator is connected in parallel with the T network.

11. The multiplexer according to claim 10, wherein the first element comprises a first inductive element, a first terminal of the first inductive element is connected to the node, and a second terminal of the first inductive element serves as a third port of the filter.

12. The multiplexer according to claim 10, wherein the first element comprises a third capacitive element, a first terminal of the third capacitive element is connected to the node, and a second terminal of the third capacitive element serves as a third port of the filter.

13. The multiplexer according to claim 10, wherein the first element comprises a first inductive element and a third capacitive element, and a circuit formed by the first inductive element and the third capacitive element connected in series or parallel is connected to the node.

14. The multiplexer according to claim 10, wherein the filter further comprises an LC filtering element, wherein the LC filtering element and the at least one filtering unit are connected in series between the first port and the second port.

15. The multiplexer according to claim 10, wherein the filter comprises at least two filtering units, and the at least two filtering units are connected in series between the first port and the second port.

16. The multiplexer according to claim 15, wherein the filter comprises a fourth port, wherein the fourth port is provided between the at least two filtering units.

17. The multiplexer according to claim 15, wherein when the filter further comprises the LC filtering unit, and the LC filtering unit is connected in series between the at least two filtering units.

18. The multiplexer according to claim 15, wherein transmission zeros of different filtering units of the at least two filtering units correspond to equal frequencies.

19. The filter according to claim 2, wherein the filter comprises at least two filtering units, and the at least two filtering units are connected in series between the first port and the second port.

20. The filter according to claim 3, wherein the filter comprises at least two filtering units, and the at least two filtering units are connected in series between the first port and the second port.
